(19) United States
(12) Patent Application Publication
(10) Pub. No.: US 2005/0172182 A1
(43) Pub. Date: Aug. 4, 2005

(54) Optimal operational voltage identification for a processor design

(76) Inventor: Elias Gedamu, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/759,867

(22) Filed: Jan. 15, 2004

(51) Int. Cl. G01R 31/28; G06F 11/00; G01R 31/30

(52) U.S. Cl. 714/724

(57) ABSTRACT

Systems, methods, and computer programs for testing a processor design are provided. One embodiment is a system comprising: means for searching a file that contains test results for a lot of wafers at two or more voltage levels; and means for determining an optimal operational voltage based on which of the two or more voltage levels had the least test failures.

### BACKGROUND

Currently, a number of systems exist for testing various types of semiconductor-based devices. In general, such systems interface with the device-under-test (DUT) and perform various analyses to test the operation, functionality, etc. of the DUT. Typically, the results of these tests are logged to a results file for subsequent analysis to assess the processor design and/or the yield of the fabrication process.

Existing systems for analyzing the results file, however, are limited because of the large size of the file. The results file is typically very large because the test system performs a number of tests for each processor on each wafer in the lot.

### SUMMARY

Systems, methods, and computer programs for testing a processor design are provided. One embodiment is a method for testing a processor design. Briefly described, one such method comprises: searching a file that contains test results for a lot of wafers at two or more voltage levels; and determining an optimal operational voltage based on which of the two or more voltage levels had the least test failures.

Another embodiment is a system for testing a processor design. Briefly described, one such system comprises: a parser module for searching a file that contains test results for a lot of wafers at two or more voltage levels; a test failure calculation module for determining how many test failures occurred at the two or more voltage levels; and an optimal operational voltage module for determining which of the two or more voltage levels had the least test failures.

A further embodiment is a computer program embodied in a computer-readable medium for testing a processor design. Briefly described, one such computer program comprises: logic configured to search a file that contains test results for a lot of wafers at two or more voltage levels; and logic configured to determine an optimal operational voltage based on which of the two or more voltage levels had the least test failures.

### BRIEF DESCRIPTION OF THE DRAWINGS

Many aspects of the invention can be better understood with reference to the following drawings. The components in the drawings are not necessarily to scale, emphasis instead being placed upon clearly illustrating principles in accordance with exemplary embodiments of the present invention. Moreover, in the drawings, like reference numerals designate corresponding parts throughout the several views.

FIG. 1 is a block diagram of a testing environment 102 for testing processors, which includes an optimal operational voltage identification system.

FIG. 2 is a perspective view illustrating a lot of wafers that may be tested in the testing environment of FIG. 1.

FIG. 3 is a more detailed block diagram of a portion of the testing environment of FIG. 1 illustrating the general components of processors on the wafers of FIG. 2.

FIG. 4 is a flowchart illustrating the architecture, operation, and/or functionality of an embodiment of the optimal operational voltage identification system of FIGS. 1 and 3.

FIG. 5 is a block diagram of another embodiment of the optimal operational voltage identification system of FIGS. 1 and 3.

### DETAILED DESCRIPTION

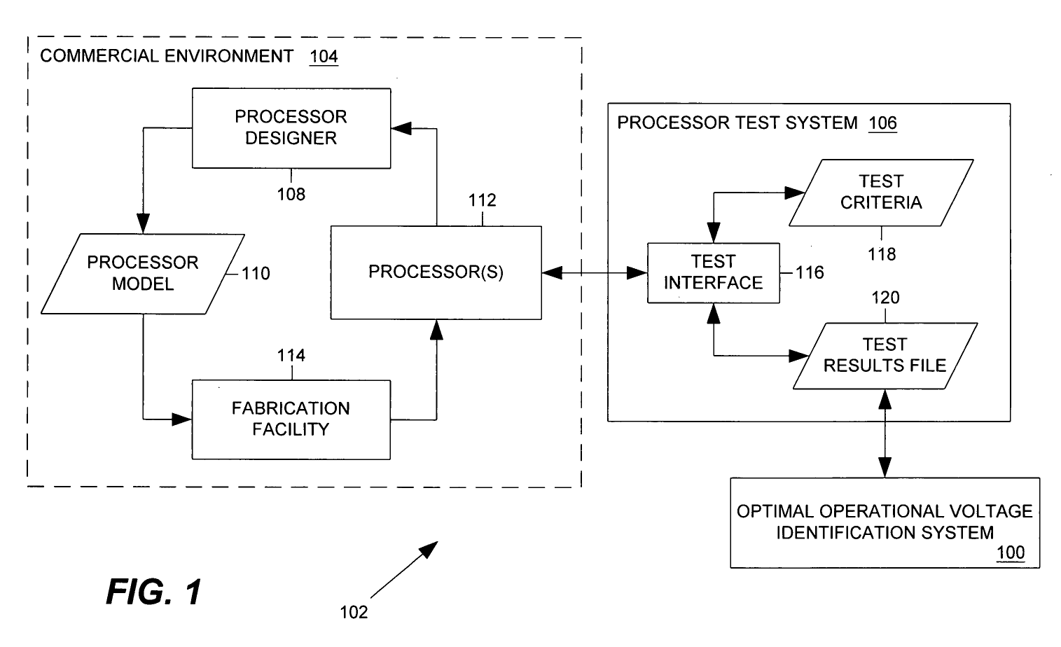

This disclosure relates to various embodiments of systems, methods, and computer programs for testing a processor design. Several embodiments will be described below with reference to FIGS. 1-5. As an introductory matter, however, the basic architecture, operation, and/or functionality of an exemplary embodiment of an optimal operational voltage identification system will be briefly described.

In the exemplary embodiment, the optimal operational voltage identification system is configured to interface with a file that contains results of various tests performed on processor(s) in a collection of wafers (i.e., lot). As known in the art, the various tests may be performed for two or more voltage levels at which the processor is configured to operate (e.g., low, nominal, high, etc.). In this regard, the optimal operational voltage identification system is configured to search the file containing the results of the tests. Based on the results of the tests for each voltage level, the optimal operational voltage identification system determines which of the voltage levels had the least test failures (e.g., in terms of quantity of failures, significance of failures, etc.). In this manner, it should be appreciated that the system identifies the optimal operational voltage level according to the original test results embodied in the test file. It should be further appreciated that this type of information may be useful to processor designers and/or manufacturers to identify problem areas in either the processor design or in the processor fabrication process.

FIG. 1 illustrates an embodiment of a processor design/manufacture/test environment 102 in which various embodiments of a optimal operational voltage identification system 100 may be implemented. As illustrated in the embodiment of FIG. 1, environment 102 comprises commercial environment 104, processor test system 106, and optimal operational voltage identification system 100. In commercial environment 104, a processor designer 108 designs a processor to be manufactured. As further illustrated in FIG. 1, the architecture, functionality, layout (or floorplan), etc. may be embodied in a processor model 110 that may be provided to a fabrication facility 114 for manufacture. Fabrication facility 114 manufacturers processors 112 according to processor model 110. It should be appreciated that any type of processor may be designed and manufactured.

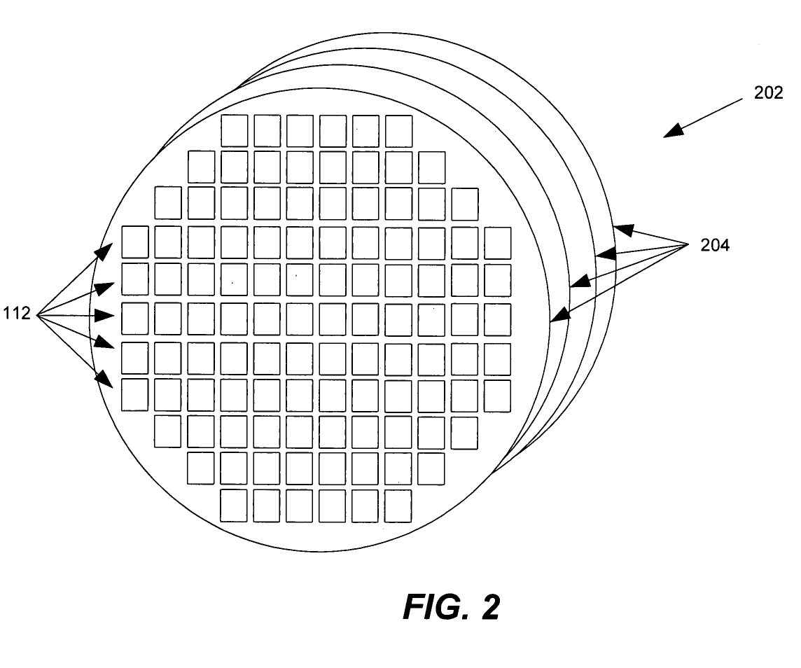

Referring to FIG. 2, it should be further appreciated that fabrication facility 114 typically manufactures a lot 202 of wafers 204. As known in the art, a wafer 204 comprises a number of processors 112. Referring again to FIG. 1, processor test system 106 may be used to test any aspect of processors 112 (e.g., operation, functionality, etc.) in lot 202, or various components of processors 112. In this regard, processor test system 106 comprises a test interface 116, test criteria 118, and a test results file 120.

Test criteria 118 may comprise a data file or logic that defines and/or controls the test(s) to be performed on processors 112. One of ordinary skill in the art will appreciate that any of a variety of types of tests may be performed on processors 112 and, therefore, test criteria 118 may be configured accordingly. As described in more detail below, various embodiments of test criteria 118 may be configured to perform tests at various voltage levels (e.g., low, nominal, high, etc.) at which processors 112 may operation.

As illustrated in FIG. 1, test interface 116 provides the interface between test criteria 118 and processors 112 to be tested. Test interface 116 may be configured to provide the physical, functional, or other interface means between these components.

As known in the art, during operation of processor test system 106, the results of the tests performed on each processor 112, wafer 204, and/or the corresponding aspects of processors 112 or wafer 204 may be logged to test results file 120. Typically, due to the large number of tests being performed and the large number of processors 112, test results file 120 is relatively large. It should be appreciated that test results file 120 may be configured in a variety of ways. For example, test results file 120 may be represented in hexadecimal, binary, or other suitable data formats.

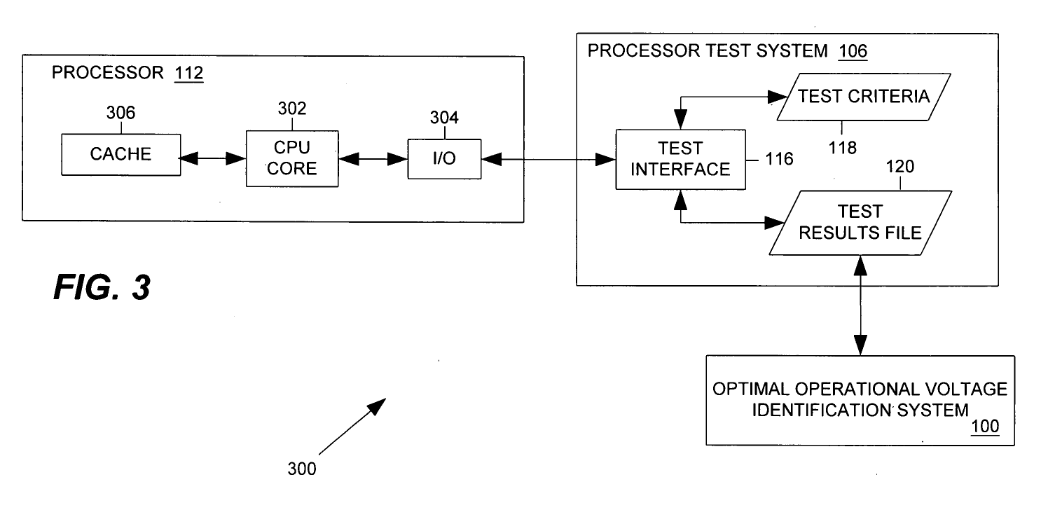

FIG. 3 illustrates an example of a processor architecture that may be employed in processors 112. In this embodiment, processor 112 comprises I/O 304, a CPU core 302, and cache 306. I/O 304 provides a mechanism by which processor test system 106 may test various aspects of processor 112. As briefly described above, optimal operational identification system 100 may be configured to search test results file 120 and, based on the results of the tests for each voltage level (e.g., low, nominal, high, etc.), the optimal operational voltage identification system determines which of the voltage levels had the least test failures. One of ordinary skill in the art will appreciate that the optimal operational voltage may be identified based on the relative quantity of test failures at each voltage level and/or the relative significance of certain types of test failures. For example, certain types of test failures may be weighed more heavily than others. In this manner, optimal operational voltage identification system 100 may be configured in a number of ways depending on the types of tests being performed.

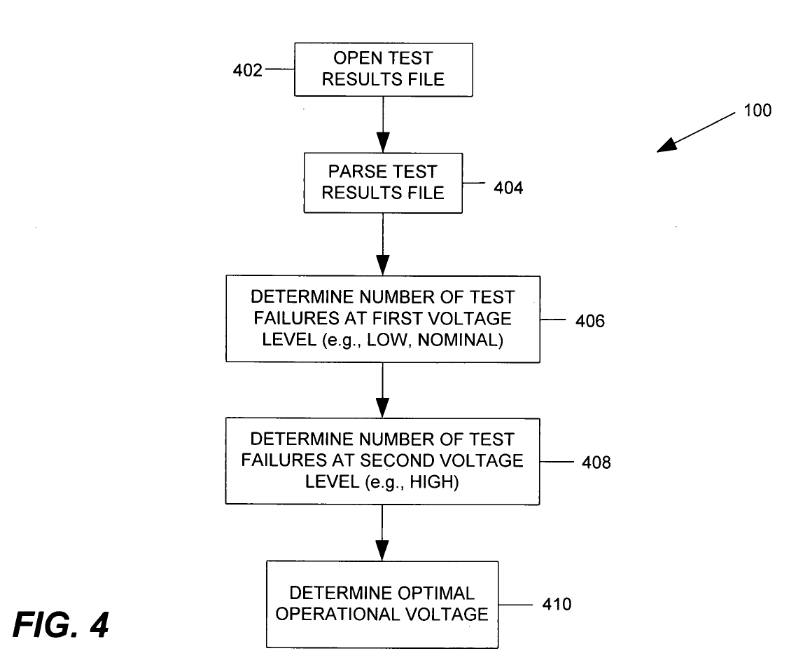

FIG. 4 illustrates the architecture, operation, and/or functionality of an embodiment of optimal operational voltage identification system 100. At block 402, optimal operational voltage identification system 100 opens test results file 120. At block 404, optimal operational voltage identification system 100 parses test results file 120. In some embodiments, test results file 120 may be compressed due to the large amount of data that it contains. In these embodiments, optimal operational voltage identification system 100 may be further configured to decompress test results file 120 and/or decode the data. At block 406, optimal operational voltage identification system 100 determines the number of test failures that occurred at the first voltage level (e.g., low, nominal). At block 408, optimal operational voltage identification system 100 determines the number of test failures that occurred at the second voltage level (e.g., high). This process may be repeated for each voltage level to be analyzed. At block 410, optimal operational voltage identification system 100 may determine the optimal operational voltage level. As mentioned above, in one embodiment, the optimal operational voltage level may be determined based on the relative quantity of test failures at each voltage level. In other embodiments, the optimal operational voltage level may take into account the relative significance of certain types of tests and weigh them accordingly.

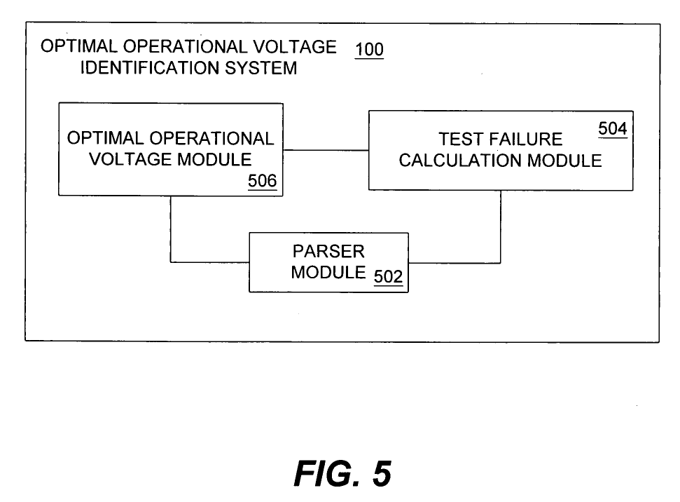

FIG. 5 illustrates another embodiment of optimal operational voltage identification system 100. In the embodiment illustrated in FIG. 5, optimal operational voltage identification system 100 comprises a parser module 502, a test failure calculation module 504, and an optimal operational voltage module 506. Parser module 502 may be configured to search test results file 120. In some embodiments, parser module 502 may be configured to open, decompress, decode, etc. test results file 120, where appropriate, to access the data in test results file 120. Test failure calculation module 504 may be configured to determine the number of test failures that occurred at each voltage level (e.g., low, nominal, high, etc.). Module 506 may be configured to determine the optimal operational voltage level based on any of a variety of rules, logic, etc. and the number of test failures for each voltage level.

One of ordinary skill in the art will appreciate that optimal operational voltage identification system 100 may be implemented in software, hardware, firmware, or a combination thereof. Accordingly, in one embodiment, optimal operational voltage identification system 100 is implemented in software or firmware that is stored in a memory and that is executed by a suitable instruction execution system. In software embodiments, optimal operational voltage identification system 100 may be written any computer language. In one exemplary embodiment, optimal operational voltage identification system 100 comprises a PERL script.

In hardware embodiments, optimal operational voltage identification system 100 may be implemented with any or a combination of the following technologies, which are all well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

It should be appreciated that the process descriptions or blocks related to FIGS. 4 and 5 represent modules, segments, or portions of code which include one or more executable instructions for implementing specific logical functions or steps in the process. It should be further appreciated that any logical functions may be executed out of order from that shown or discussed, including substantially concurrently or in reverse order, depending on the functionality involved, as would be understood by those reasonably skilled in the art.

Furthermore, optimal operational voltage identification system 100 may be embodied in any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any means that can contain, store, communicate, propagate, or transport the program for use by or in connection with the instruction execution system, apparatus, or device. The computer-readable medium can be, for example but not limited to, an electronic, magnetic, optical, electromagnetic, infrared, or semiconductor system, apparatus, device, or propagation medium. More specific examples (a nonexhaustive list) of the computer-readable medium would include the following: an electrical connection (electronic) having one or more wires, a portable computer diskette (magnetic), a random access memory (RAM) (electronic), a read-only memory (ROM) (electronic), an erasable programmable read-only memory (EPROM or Flash memory) (electronic), an optical fiber (optical), and a portable compact disc read-only memory (CDROM) (optical). Note that the computer-readable medium could even be paper or another suitable medium upon which the program is printed, as the program can be electronically captured, via for instance optical scanning of the paper or other medium, then compiled, interpreted or otherwise processed in a suitable manner if necessary, and then stored in a computer memory.

1. A method for testing a processor design, the method comprising:
searching a file that contains test results for a lot of wafers at two or more voltage levels; and
determining an optimal operational voltage based on which of the two or more voltage levels had the least test failures.

2. The method of claim 1, wherein the searching the file comprises parsing the file.

3. The method of claim 1, wherein the searching the file comprises opening the file and parsing the file.

4. The method of claim 1, wherein the determining an optimal operational voltage comprises:
determining the number of test failures at a first voltage level;
determining the number of test failures at a second voltage level; and
determining which of the first voltage level and the second voltage level had the least test failures.

5. The method of claim 1, wherein the searching the file comprises decompressing the file.

6. A system for testing a processor design, the system comprising:
a parser module for searching a file that contains test results for a lot of wafers at two or more voltage levels;
a test failure calculation module for determining how many test failures occurred at the two or more voltage levels; and
an optimal operational voltage module for determining which of the two or more voltage levels had the least test failures.

7. The system of claim 6, wherein the parser module is configured to open the file.

8. The system of claim 6, wherein the parser module, the test failure calculation module, and the optimal operational voltage module comprise software that is executed by a processor.

9. The system of claim 6, wherein the parser module is configured to decompress the file.

10. The system of claim 6, wherein the parser module, the test failure calculation module, and the optimal operational voltage module comprise a PERL script.

11. A computer program embodied in a computer-readable medium for testing a processor design, the program comprising:
logic configured to search a file that contains test results for a lot of wafers at two or more voltage levels; and
logic configured to determine an optimal operational voltage based on which of the two or more voltage levels had the least test failures.

12. The program of claim 11, wherein the logic configured to search is further configured to decompress the file.

13. The program of claim 12, wherein the logic configured to search is further configured to parse the file.

14. The program of claim 11, wherein the logic configured to determine an optimal operational voltage comprises logic configured to:
determine the number of test failures at a first voltage level;
determine the number of test failures at a second voltage level; and
determine which of the first voltage level and the second voltage level had the least test failures.

15. A system for testing a processor design, the system comprising:
means for searching a file that contains test results for a lot of wafers at two or more voltage levels; and
means for determining an optimal operational voltage based on which of the two or more voltage levels had the least test failures.
